(19) United States
(12) Patent Application Publication
(10) Pub. No.: US 2025/0293698 A1
(43) Pub. Date: Sep. 18, 2025

(54) SYNCHRONIZATION OF FREQUENCY DIVIDED REFERENCE CLOCKS

(71) Applicant: Space Exploration Technologies Corp., Hawthorne, CA (US)

(72) Inventors: Alex Ahmad Mirzaei, Tustin, CA (US); Omid Nasiby, Laguna Niguel, CA (US); David Francois Jacquet, Vaulnaveys le Haut (FR); Masoud Kahrizi, Irvine, CA (US); Ka Shun Carson Pun, Irvine, CA (US)

(21) Appl. No.: 19/073,713

(22) Filed: Mar. 7, 2025

Related U.S. Application Data
(60) Provisional application No. 63/564,283, filed on Mar. 12, 2024.

(51) Int. Cl. H03L 7/191

(52) U.S. Cl. CPC H03L 7/191

(57) ABSTRACT

Systems and techniques for synchronizing serializer and deserializer digital reference clocks are described. An example method includes activating a phase locked loop (PLL) to generate an ADC/DAC reference signal, obtaining a DAC Enable (DAC_EN) signal, generating, based on the DAC_EN signal, a SET signal aligned with a phase of the ADC/DAC reference signal, generating, based on the ADC/DAC reference signal, a serializer digital reference clock for a serializer coupled to the DAC, and generating, based on the ADC/DAC reference signal and the SET signal, a deserializer digital reference clock for a deserializer coupled to the ADC. The serializer digital reference clock and the deserializer digital reference clock are each respectively generated by frequency division of the ADC/DAC reference signal. The serializer digital reference clock and the deserializer digital reference clock are synchronized to a known phase based on the SET signal.

### CROSS-REFERENCE TO RELATED APPLICATIONS

The present application claims the benefit of, and priority to, U.S. Provisional Patent Application No. 63/564,283 filed Mar. 12, 2024 entitled “SYNCHRONIZATION OF FREQUENCY DIVIDED REFERENCE CLOCKS”, the contents of which are hereby incorporated by reference in their entirety.

### BACKGROUND

Phased array antennas are used in a variety of wireless communication systems such as satellite and cellular communication systems. The phased array antennas can include a number of antenna elements arranged to behave as a larger directional antenna. Moreover, a phased array antenna can be used to increase an overall directivity and gain, steer the angle of array for greater gain and directivity, perform interference cancellation from one or more directions, determine the direction of arrival of received signals, and improve a signal to interference ratio, among other things. Advantageously, a phased array antenna can be configured to implement beamforming techniques to transmit and/or receive signals in a preferred direction without physically repositioning or reorientation.

One of the many design challenges for phased array antennas is Local Oscillator (LO) frequency planning. LO frequency planning refers to the selection of the LO frequencies. In order to operate over different frequency bands, a beamformer (BF) includes one or more Phase Locked Loops (PLLs) to generate LO signals necessary for down conversion and/or up conversion. In some cases, phased array antennas supporting carrier aggregation may require LO signals for multiple different frequency band combinations. The number of different frequency band combinations that have to be supported by the BF for carrier aggregation is large and new combinations are being introduced all the time. Many of these combinations require multiple PLLs to be enabled simultaneously.

One challenge in frequency planning that is particularly problematic for a BF comes from the fact that the controlled oscillators (COs) in the PLLs are sensitive to interference. For example, two PLLs running at the same frequency, or approximately the same frequency, interfere with each other. This interference degrades the noise performance of the PLLs. This same problem occurs if the PLLs run at frequencies that have a harmonic relation (i.e., a harmonic of the LO frequency of one PLL is the same as or approximately the same as the LO frequency of another PLL). In a receiver, this interference results in degradation of throughput due to phase noise sidebands in the LO signal used for down conversion. During down conversion (i.e., mixing), these phase noise sidebands mix parts of the received signal on top of itself.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one illustrative embodiment, an apparatus for synchronizing digital reference signals for digital-to-analog converter (DAC) serializers and analog-to-digital convert (ADC) deserializers is provided. The apparatus includes a PLL configured to obtain generate an ADC/DAC reference signal, a SET signal generator included within a DAC and configured to obtain a DAC_EN signal and to generate a SET signal based on an activation of the DAC_EN signal, wherein the SET signal is aligned with a phase of the ADC/DAC reference signal, a first digital reference clock generator associated with the DAC and configured to generate a serializer digital reference clock based on the ADC/DAC reference signal by frequency dividing the ADC/DAC reference signal, and a second digital reference clock generator associated with an ADC and configured to generate a deserializer digital reference clock based on the ADC/DAC reference signal by frequency dividing the ADC/DAC reference signal, wherein the serializer digital reference clock and the deserializer digital reference clock are synchronized to a known phase based on the SET signal.

In another illustrative embodoment, a method for synchronizing digital reference signals for DAC serializers and ADC deserializers is provided. The method includes activating a phase locked loop (PLL) of a radio frequency (RF) communication system to generate an ADC/DAC reference signal, obtaining a DAC Enable (DAC_EN) signal at a DAC, generating, based on the DAC_EN signal, a SET signal, wherein the SET signal is aligned with a phase of the ADC/DAC reference signal, generating, at a first digital reference clock generator associated with the DAC, based on the ADC/DAC reference signal, a serializer digital reference clock for a serializer coupled to the DAC, and generating, at a second digital reference clock generator associated with an ADC, based on the ADC/DAC reference signal and the SET signal, a deserializer digital reference clock for a deserializer coupled to the ADC, wherein: the serializer digital reference clock and the deserializer digital reference clock are each respectively generated by frequency division of the ADC/DAC reference signal, and the serializer digital reference clock and the deserializer digital reference clock are synchronized to a known phase based on the SET signal.

In another illustrative embodiment, a non-transitory computer-readable medium is provided that has stored thereon instructions that, when executed by one or more processors, cause the one or more processors to: activate a phase locked loop (PLL) of a radio frequency (RF) communication system to generate an ADC/DAC reference signal, obtain a DAC Enable (DAC_EN) signal at a DAC, generate, based on the DAC_EN signal, a SET signal, wherein the SET signal is aligned with a phase of the ADC/DAC reference signal, generate, at a first digital reference clock generator associated with the DAC, based on the ADC/DAC reference signal, a serializer digital reference clock for a serializer coupled to the DAC, and generate, at a second digital reference clock generator associated with an ADC, based on the ADC/DAC reference signal and the SET signal, a deserializer digital reference clock for a deserializer coupled to the ADC, wherein: the serializer digital reference clock and the deserializer digital reference clock are each respectively generated by frequency division of the ADC/DAC reference signal, and the serializer digital reference clock and the deserializer digital reference clock are synchronized to a known phase based on the SET signal.

In another example, an apparatus for for synchronizing digital reference signals for DAC serializers and ADC deserializers is provided. The apparatus includes: means for activating a phase locked loop (PLL) of a radio frequency (RF) communication system to generate an ADC/DAC reference signal, means for obtaining a DAC Enable (DAC_EN) signal at a DAC, means for generating, based on the DAC_EN signal, a SET signal, wherein the SET signal is aligned with a phase of the ADC/DAC reference signal, means for generating, at a first digital reference clock generator associated with the DAC, based on the ADC/DAC reference signal, a serializer digital reference clock for a serializer coupled to the DAC, and means for generating, at a second digital reference clock generator associated with an ADC, based on the ADC/DAC reference signal and the SET signal, a deserializer digital reference clock for a deserializer coupled to the ADC, wherein: the serializer digital reference clock and the deserializer digital reference clock are each respectively generated by frequency division of the ADC/DAC reference signal, and the serializer digital reference clock and the deserializer digital reference clock are synchronized to a known phase based on the SET signal.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is an illustration of a block diagram of at least a portion of a communication system, in accordance with some embodiments of the present disclosure;

FIG. 2 is simplified example of a DAC and ADC pair within a communication system showing circuitry or electrical components for converting between analog and digital signals, in accordance with some embodiments of the present disclosure;

FIG. 3A through FIG. 3D are illustrations showing circuitry for generating serializer/deserializers digital reference clocks by dividing an ADC/DAC reference signal, in accordance with some embodiments of the present disclosure;

FIG. 4 is an illustration of timing waveforms with different delays that can be used for removing delay ambiguity between a DAC and an ADC, in accordance with some embodiments of the present disclosure;

FIG. 5 is an illustration of timing waveforms showing a transient response of a timing waveform that can be used for removing delay ambiguity between a DAC and an ADC, in accordance with some embodiments of the present disclosure;

FIG. 6 is a flowchart depicting a method of removing delay ambiguity between a DAC and an ADC in a communication system in accordance with some embodiments of the present disclosure.

### DETAILED DESCRIPTION

The present disclosure relates to various systems, apparatuses, and methods related to synchronizing and/or removing delay ambiguity from frequencies generated by one or more frequency dividers. In particular, the systems, apparatuses, and methods relate to removing phase ambiguity from various divided frequencies generated based on a local oscillator (LO) signal. In various embodiments, the disclosed system is included within a larger communications system, such as but not limited to satellite communication systems. Additionally, the communications system may further include or be in communication with one or more antenna elements configured for wireless communication systems.

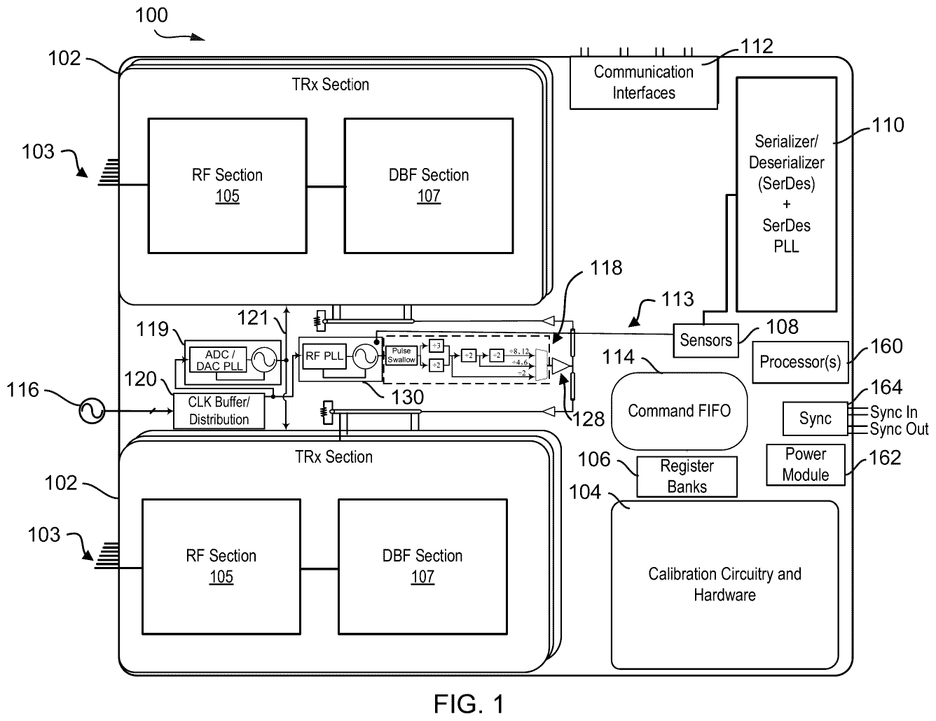

Referring now to FIG. 1, one example of the communication system 100 in accordance with aspects of the present disclosure is shown. In one or more embodiments, the communication system 100 is included within or may be used to facilitate a wireless communications system, a wideband communications system, a satellite-based communications system, a terrestrial-based communications system, a non-geostationary (NGO) satellite communications system, a low Earth orbit (LEO) satellite communications system, and/or the like. For example, and without limitation, the communication system 100 can also include and/or be included in a satellite, a user terminal associated with user device(s), a gateway, a repeater, or other device capable of receiving and transmitting signals with another device of a satellite communications system.

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. Additionally, it should be appreciated that items included in a list in the form of “at least one A, B, and C” can mean (A); (B); (C); (A and B); (B and C); (A and C); or (A, B, and C). Similarly, items listed in the form of “at least one of A, B, or C” can mean (A); (B); (C); (A and B); (B and C); (A and C); or (A, B, and C).

Language such as “top surface”, “bottom surface”, “vertical”, “horizontal”, and “lateral” in the present disclosure is meant to provide orientation for the reader with reference to the drawings and is not intended to be the required orientation of the components or to impart orientation limitations into the claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, it may not be included or may be combined with other features.

Many embodiments of the technology described herein may take the form of computer- or controller-executable instructions, including routines executed by a programmable computer or controller. Those skilled in the relevant art will appreciate that the technology can be practiced on computer/controller systems other than those shown and described above. The technology can be embodied in a special-purpose computer, controller or data processor that is specifically programmed, configured or constructed to perform one or more of the computer-executable instructions described above. Accordingly, the terms “computer” and “controller” as generally used herein refer to any data processor and can include Internet appliances and hand-held devices (including palm-top computers, wearable computers, cellular or mobile phones, multi-processor systems, processor-based or programmable consumer electronics, network computers, minicomputers and the like). Information handled by these computers can be presented at any suitable display medium, including an organic light emitting diode (OLED) display or liquid crystal display (LCD). These and other aspects of the present disclosure will be more fully described below.

A radio frequency (RF) device (e.g., an interstellar satellite communication system) may transmit and receive data for two-way communication with a wireless communication system. The wireless device may include a transmitter for data transmission and a receiver for data reception. For data transmission, the transmitter may modulate a transmit LO signal with data to obtain a modulated RF signal, amplify the modulated RF signal to obtain an output RF signal having the desired output power level, and transmit the output RF signal via an antenna to a base station. For data reception, the receiver may obtain a received RF signal via the antenna, amplify and down convert the received RF signal with a receive LO signal, and process the down converted signal to recover data sent by the base station.

The RF device may include one or more oscillators to generate one or more oscillator signals at one or more desired frequencies. The oscillator signal(s) may be used to generate the transmit LO signal for the transmitter and/or the receive LO signal for the receiver. The oscillator(s) may be required to generate the oscillator signal(s) to meet the requirements of the wireless communication system with which the RF device communicates.

Frequency dividers are used extensively for generating reference signals, such as LO signals, reference RF signals, serializer clocks, and/or deserializers clocks. When frequency dividers are used within a phase locked loop (PLL), the reference signals can have a known phase. In some cases, external frequency dividers may be used to generate reference signal frequencies over a wider range of frequencies than can be supported by a single PLL. However, the use of frequency dividers outside of the PLL may give rise to phase ambiguity of the frequency divided reference signal. In the context of single chips transceivers including analog-to-digital converters (ADCs) and digital-to-analog converters (DACs), phase ambiguity can result in delay ambiguity.

In some cases, Code-Division Multiple Access (CDMA) calibration techniques can be used to detect and correct phase ambiguity in reference signals generated using external frequency dividers. In some applications, CDMA calibration may have drawbacks including but not limited to it being a time-consuming process that requires its own overhead.

In light of the discussion above, there is a need for systems and techniques for mitigating phase ambiguity in generation of reference signals generated using external frequency dividers. For example, the systems and techniques described herein can be used to remove phase ambiguity in the generation of reference signals for serializers and/or deserializers based on frequency division of an ADC/DAC reference signal.

Referring now to FIG. 1, an example illustration of a block diagram of at least a portion of a communication system 100 in accordance with some embodiments of the present disclosure is shown. In some cases, the communication system 100 can be a component included in a phased array antenna system. According to at least one aspect, the communication system 100 includes one or more transmit/receive (TRx) sections 102. In particular, the TRx sections 102 can include circuitry to facilitate digital beamforming for transmitting and/or receiving data in phased array antenna system. In particular, the TRx sections 102 may be associated with respective antenna elements for transmitting radio frequency (RF) signals formed at the TRx sections and/or receiving RF signals over-the-air (OTA). In some cases, the TRx sections 102 include RF sections 105 for up-conversion and/or down-conversion of RF signals.

In some implementations, the TRx sections 102 may be included in one or more IC chips. In some examples, each TRx section 102 may be associated with an RF input/output (RFIO) 103 of the communication system 100. In one illustrative example, the communication system 100 can include sixteen TRx sections 102 and sixteen RFIOs 103, each RFIO corresponding to a respective one of the TRx sections. In another illustrative example, the communication system 100 can include thirty-two (32) TRx sections 102 and thirty-two RFIOs 103, each RFIO corresponding to a respective one of the TRx sections.

According to various aspects, the communication system 100 may also include a calibration module 104, one or more register banks 106, one or more sensors 108, one or more serializer/deserializers (SerDes) 110, one or more communication interfaces 112, a command pipeline 114 (e.g., a first-in-first-out (FIFO) pipeline), local oscillator generator 118, ADC/DAC PLL 119, reference clock buffer and distribution network 120, one or more buffers 128, RF phase locked loop (PLL) 130, one or more processors 160, power module 162, and synchronization module 164.

In some cases, the communication system 100 can be communicatively coupled to a modem (not shown). The communication system 100 can include one or more processors 160, one or more register banks 106, and command pipeline for processing instructions obtained from the modem. In some cases, the communication system 100 can communicate with the modem via the SerDes 110. In some cases, the SerDes 110 can include a SerDes PLL.

In some implementations, the communication system 100 can include one or more sensors 108 for monitoring operation of various components of the communication system 100. For example, a temperature sensor 113 can be used to monitor temperature of one or more PLLs e.g., RF PLL 130, SerDes PLL, ADC/DAC PLL 119). In some cases, temperature measurements of a PLL can be used to compensate for frequency drift that can be associated with temperature changes.

As illustrated, the communication system 100 includes a power module 162. In some cases, the power module can include a power-on-reset (POR) circuit. In some implementations, the power module 162 can output an active low POR signal (nPOR). In some cases, the power module 162 can include fuses, power limiters, power monitoring circuitry, or the like for protecting the communication system 100 from damage.

In some cases, the communication system 100 can include a synchronization module 164. In some cases, the synchronization module 164 can include one or more sync inputs (“Sync In”) configured to receive one or more synchronization signals (e.g., L1_sync signals) that can be used to coordinate operations between two or more communication systems included in a phased array antenna system. In some cases, the synchronization module 164 can include one or more synchronization outputs (“Sync Out”) that can be used to provide synchronization signals to other components in the phased array antenna system. In one illustrative example, one or more synchronization outputs can be coupled to synchronization inputs of an additional communication system. In some cases, multiple communication systems be linked in a daisy-chain configuration for sharing synchronization signals. In some cases, the synchronization module 164 can include circuitry for generating additional synchronization signals (e.g., L2_sync signals). In one illustrative example, the communication system 100 can generate L2_sync signals based on received L1_sync signals and perform synchronization of various operations based on the L2_sync signal.

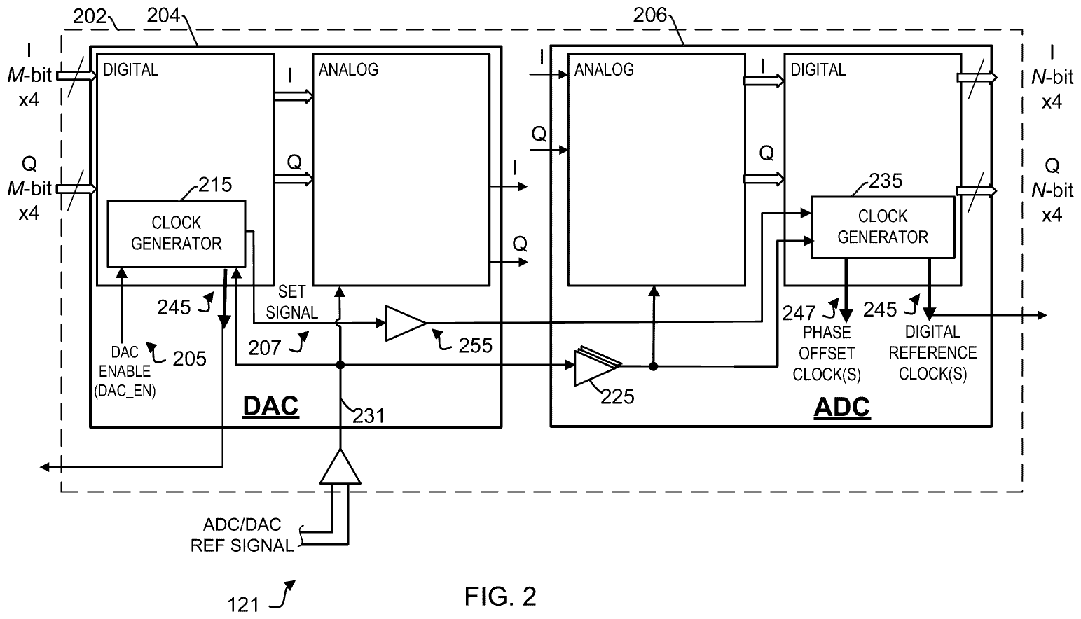

In the illustrated example, ADC/DAC PLL 119 receives the reference clock 116 from the reference clock buffer and distribution network 120. The ADC/DAC PLL 119 can generate and output an ADC/DAC reference signal 121 based on the reference clock 116. In some cases, the ADC/DAC reference signal 121 can be a single-ended signal as shown in FIG. 1. In some examples (see FIG. 2), the ADC/DAC reference signal 121 can be a differential signal. In the illustrated example, the reference clock 116 can include an external reference clock received by the communication system 100 which can be buffered and distributed by the reference clock buffer and distribution network 120. In the illustrated example, the ADC/DAC reference signal 121 can be provided to the TRx sections 102. In some cases, the ADC/DAC reference signal 121 can be provided to digital beamformer (DBF) sections 107 of the TRx sections 102. In some cases, one or more buffers (not shown) and/or a distribution network (not shown) can be provided for distributing the ADC/DAC reference signal 121 to the TRx sections 102.

As shown in FIG. 2, a portion of an example TRx section 202 includes an associated DAC 204 and an ADC 206. In the illustrated example of FIG. 2, the portion of the TRx section 202 can correspond to TRx sections 102 of FIG. 1. According to various aspects, the ADCs and DACs included in portion of the TRx sections 202 may operate using an ADC/DAC reference signal 121 that typically operates at a high frequency. For example, the frequency of the ADC/DAC reference signal 121 can be configured to be at least twice the bandwidth of the signal being converted. By way of example and not limitation, the ADC/DAC reference signal 121 frequency may be approximately 980 MHz. In the illustrated example of FIG. 2, the ADC/DAC reference signal 121 is a differential signal and is converted within the portion of the TRx section 202 to a single ended internal ADC/DAC reference signal 231.

In some cases, the DAC 204 and the ADC 206 may interact with signals in the digital domain that operate at lower frequencies than the ADC/DAC reference signal 121. For example, the DAC 204 may include one or more serializers (not shown) for converting multiple parallel data streams at a frequency below the ADC/DAC reference signal 121 frequency into one or more serial data streams at the ADC/DAC reference signal frequency. As illustrated in the example of FIG. 2, a digital section of the DAC 204 can receive four M-bit wide parallel data streams for the I channel and four M-bit wide parallel data streams for the Q channel, where M is an integer. In some examples, each individual M-bit wide parallel data stream of the M-bit wide parallel data streams can operate at ¼th of the ADC/DAC reference signal 121 frequency. In some examples, the serializer (not shown) can serialize the four M-bit wide parallel data streams for the I channel into an I serial data stream at the ADC/DAC reference signal 121 frequency. Similarly, in some cases, the serializer (not shown) can serialize the four M-bit wide parallel data streams for the Q channel into a Q serial data stream at the ADC/DAC reference signal 121 frequency.

Similarly, the ADC 206 may include a deserializer for converting a serial data stream at the ADC/DAC reference signal 121 frequency into multiple parallel data streams at a frequency below the ADC/DAC reference signal frequency. In the illustrated example of FIG. 2, an analog section of the ADC 206 can obtain analog signals from an analog I channel and an analog Q channel (e.g., from antenna elements of the antenna array). In some cases, the ADC 206 can convert the analog signals from the analog I channel into an I serial data stream at the ADC/DAC reference signal 121 frequency. In some examples, the ADC 206 can convert the analog signals from the analog Q channel into a Q serial data stream at the ADC/DAC reference signal 121 frequency. As illustrated in FIG. 2, a digital section of the ADC 206 can convert the I serial data stream at the ADC/DAC reference signal 121 frequency into four parallel N-bit wide data streams for the I channel at ¼th the ADC/DAC reference signal 121 frequency, where N is an integer. Similarly, the digital section of the ADC 206 can convert the Q serial data stream at the ADC/DAC reference signal 121 frequency into four parallel N-bit wide data streams for the I channel at ¼th the ADC/DAC reference signal 121 frequency.

According to one illustrative example, every time communication system (e.g., communication system 100 of FIG. 1), including the portion of the TRx section 202, is booted up or each time the portion of the TRx section 202 is initiated, the ADC 206 and DAC 204 included in the portion of the TRx section 202 receive the ADC/DAC reference signal 121 and generate reference signals for serializers and/or deserializers based on the single ended internal ADC/DAC reference signal 231. As shown in FIG. 2, one or more buffers 225 and/or a distribution network (not shown) may be used to amplify the single ended internal ADC/DAC reference signal 231 and may introduce a variable delay to the single ended internal ADC/DAC reference signal 231 received at the ADC 206. In one illustrative aspect, the variable delay may be between approximately 20 picosecond (ps) and 80 ps.

According to one aspect, in order to generate digital reference clocks for serializers and/or deserializers, one or more clock generators 215, 235 may be employed. In the illustrated example of FIG. 2, a clock generator 215 is provided to generate digital reference clocks for the DAC (e.g., for one or more serializers) and clock generator 235 is provided to generate digital reference clocks for the ADC (e.g., for one or more deserializers). In some implementations (not shown), a single clock generator may be used for generating digital reference clocks for the portion of the TRx section 202 without departing from the scope of the present disclosure.

It should be understood that the configuration illustrated in FIG. 2 is provided for the purposes of illustration only and the configuration can be varied without departing from the scope of the present disclosure. For example, while the example DAC 204 and ADC 206 in the illustrative example of FIG. 2 are shown to communicate with four parallel data streams operating at ¼th of the ADC/DAC reference signal 121 frequency, it should be understood that a different number of parallel data streams can be used without departing from the scope of the present disclosure. For example, a serializer can be used to convert eight parallel data streams operating at ⅛th of the ADC/DAC reference signal 121 frequency into a serial data stream operating at the ADC/DAC reference signal 121 frequency.

### Generation of Digital Reference Clock for DAC

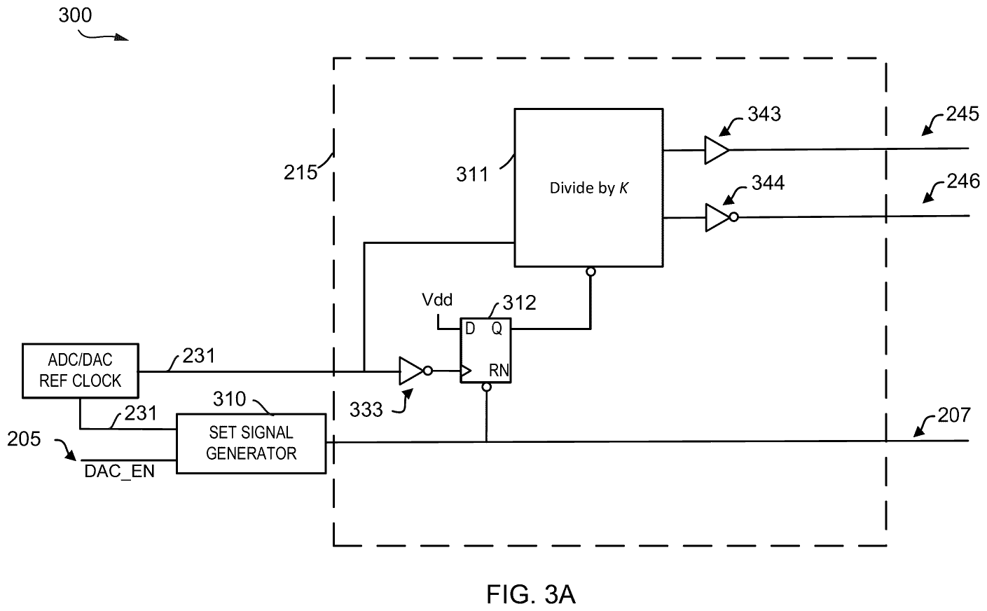

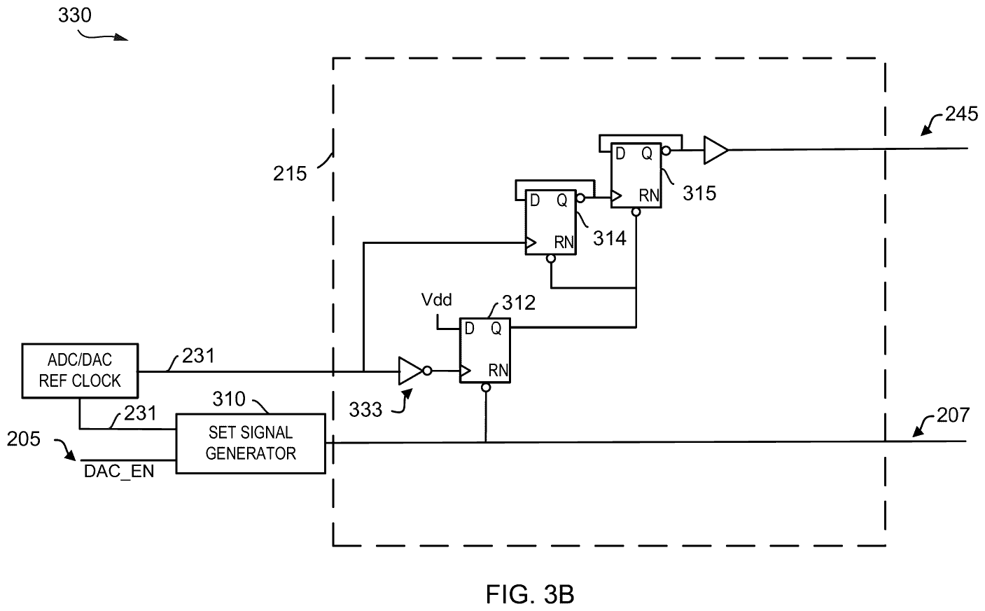

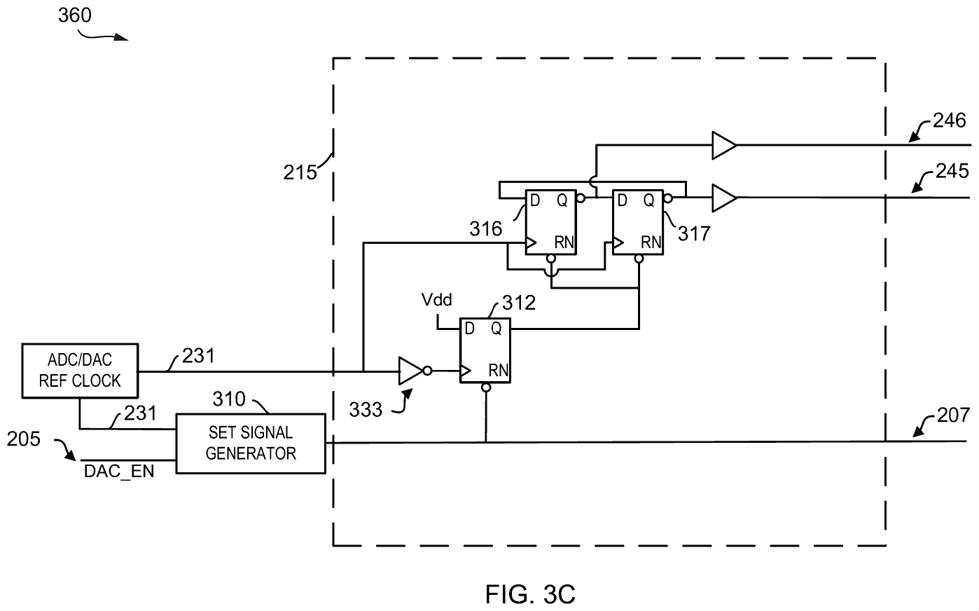

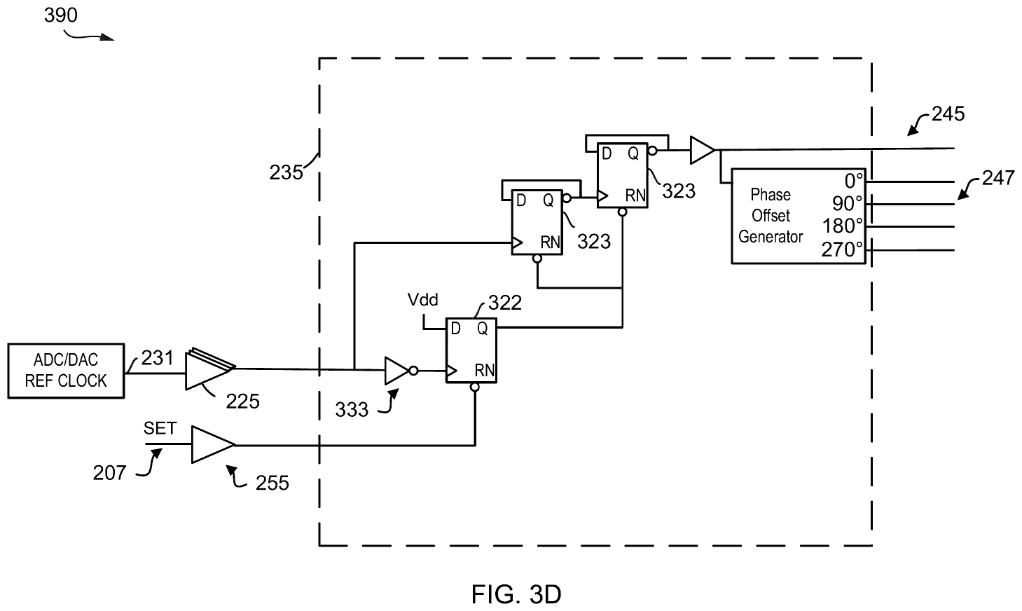

FIG. 3A illustrates an example configuration 300 for generating digital reference clocks using clock generator 215. As illustrated, the clock generator 215 obtains the single ended internal ADC/DAC reference signal 231 as an input. In the illustrated example, the clock generator 215 includes a frequency divider 311, such as a divide by K, where K is an integer. For example, the frequency divider 311 can be used to generate a digital reference clock 245 having a frequency of 1/K times the single ended internal ADC/DAC reference signal 231 frequency. In one illustrative example, the frequency divider 311 can be implemented as a divide by four (x/4) frequency divider (e.g., K=4).

As illustrated, the clock generator 215 includes a FF 312 configured to enable generation of one or more digital reference clocks 245, 246 only when a DAC ENABLE (DAC_EN) signal 205 is activated. In some implementations, the DAC_EN signal 205 can be a signal derived based on one or more synchronization signals (e.g., L1_sync, L2_sync) that may be used for synchronization operations between various components of a communication system (e.g., communication system 100 of FIG. 1). In the illustrated example of FIG. 3A, the DAC_EN signal 205 is connected to a SET signal generator 310. The SET signal generator can be used to synchronize the DAC_EN signal 205 to the ADC/DAC reference signal 231. As illustrated, the SET signal 207 output by the SET signal generator 310 can be coupled to an active low reset port of the FF 312. Accordingly, as long as SET signal 207 has a low voltage (logical “0”), the output of the FF 312 will be reset to a low voltage (logical “0”). As illustrated, the frequency divider 311 has an active low reset port connected to the output of the FF 312. Accordingly, until the FF 312 outputs a high voltage (logical “1), the frequency divider 311 will be disabled.

As illustrated in FIG. 3A, an inverter 333 can cause the frequency divider 311 to change its output upon the first negative edge of the single ended internal ADC/DAC reference signal 231 after the SET signal 207 is enabled with a high voltage (logical “1’). As illustrated, the input voltage to the D port of the FF 312 can be coupled to a rail voltage Vdd, which can also be a high voltage (logical “1”). Accordingly, the output of the FF 312 can also be driven to the high voltage (logical “1”) upon the first negative edge of the single ended internal ADC/DAC reference signal 231 after the SET signal 207 is enabled. In turn, the frequency divider 311 will no longer be reset by the FF 312 and can begin frequency division of the single ended internal ADC/DAC reference signal 231 on the next rising edge of the single ended internal ADC/DAC reference signal 231. In the illustrated example of FIG. 3A, the frequency divider 311 is shown with two outputs. As illustrated, a first output of the frequency divider 311 can be buffered by a non-inverting buffer 343 to generate a first digital reference clock 245 output by the clock generator 215. In addition, a second output of the frequency divider 311 can be inverted by an inverter 344 to generate a second digital reference clock 246 output by the clock generator 215 that is 180 degrees out of phase with the phase of the first digital reference clock 245. While the illustrated example of FIG. 3A illustrates a non-inverting buffer 343 and an inverter 344 for generating digital reference clocks 245, 246 with different phases (e.g., 180 degrees out of phase), it should be understood that different techniques can be used for generating different digital reference clock phases without departing from the scope of the present disclosure.

In some cases, the clock generator 215 may output a single digital reference clock without departing from the scope of the present disclosure. In some examples, the clock generator 215 may output three or more different digital reference clock phases without departing from the scope of the present disclosure.

FIG. 3B provides an illustrative example configuration 330 for generating digital reference clocks using clock generator 215 with an asynchronous, two-stage frequency divider. As illustrated, the clock generator 215 obtains the single ended internal ADC/DAC reference signal 231 as an input. In the illustrated example, the clock generator 215 uses a pair of flip-flops (FFs) 314, 315 each configured as divide by two (x/2) frequency dividers connected in series to generate a digital reference clock 245 having a frequency of one fourth (1/4^{th}) of the single ended internal ADC/DAC reference signal 231 frequency.

As illustrated, the example configuration 330 for generating digital reference clocks using the clock generator 215 of FIG. 3B includes a FF 312 configured to enable generation of the digital reference clock 245 only when a DAC_EN signal 205 is activated. As noted above, the DAC_EN signal 205 can be a signal derived based on one or more synchronization signals (e.g., L1_sync, L2_sync) that may be used for synchronization operations between various components of a communication system (e.g., communication system 100 of FIG. 1). In the illustrated example of FIG. 3B, the DAC_EN signal 205 is connected to a SET signal generator 310. The SET signal generator can be used to synchronize the DAC_EN signal 205 to the ADC/DAC reference signal 231. As illustrated, the SET signal 207 output by the SET signal generator 310 can be coupled to an active low reset port of the FF 312. Accordingly, as long as SET signal 207 has a low voltage (logical “0”), the output of the FF 312 will be reset to a low voltage (logical “0”). As illustrated, the pair of FFs 314, 315 of the frequency divider have active low reset ports connected to the output of the FF 312. Accordingly, until the FF 312 outputs a high voltage (logical “1), the FFs 314, 315 will be disabled.

As illustrated in FIG. 3B, an inverter 333 can cause the FF 312 to change its output upon the first negative edge of the single ended internal ADC/DAC reference signal 231 after the SET signal 207 is enabled with a high voltage (logical “1’). As illustrated, the input voltage to the D port of the FF 312 can be coupled to a rail voltage Vdd, which can also be a high voltage (logical “1”). Accordingly, the output of the FF 312 can also be driven to the high voltage (logical “1”) upon the first negative edge of the single ended internal ADC/DAC reference signal 231 after the SET signal 207 is enabled. In turn, the FFs 314, 315 will no longer be reset by the FF 312 and can begin frequency division of the single ended internal ADC/DAC reference signal 231 on the next rising edge of the single ended internal ADC/DAC reference signal 231. In the illustrated example of FIG. 3B, the inverting output of FF 314 is coupled to the input of FF 314 and to a clock port of the FF 315. As illustrated, the inverting output of FF 315 is coupled to the input of FF 315 and buffered to generate the digital reference clock 245.

FIG. 3C provides an additional illustrative example configuration 360 for generating digital reference clocks using clock generator 215 with synchronous, two-stage frequency divider. As illustrated, the clock generator 215 in the example configuration 360 obtains the single ended internal ADC/DAC reference signal 231 as an input. In the illustrated example, the clock generator 215 uses a pair of FFs 316, 317 each configured as divide by two (x/2) frequency dividers connected in series to generate a digital reference clock 245 having a frequency of one fourth (1/4^{th}) of the single ended internal ADC/DAC reference signal 231 frequency.

As illustrated, the example configuration 360 for generating digital reference clocks using the clock generator 215 of FIG. 3C includes a FF 312 configured to enable generation of the digital reference clock 245 only when the DAC_EN signal 205 is activated. As noted above, the DAC_EN signal 205 can be a signal derived based on one or more synchronization signals (e.g., L1_sync, L2_sync) that may be used for synchronization operations between various components of a communication system (e.g., communication system 100 of FIG. 1). In the illustrated example of FIG. 3C, the DAC_EN signal 205 is connected to a SET signal generator 310. The SET signal generator can be used to synchronize the DAC_EN signal 205 to the ADC/DAC reference signal 231. As illustrated, the SET signal 207 output by the SET signal generator 310 can be coupled to an active low reset port of the FF 312. Accordingly, as long as SET signal 207 has a low voltage (logical “0”), the output of the FF 312 will be reset to a low voltage (logical “0”). As illustrated, the first FF 316 of the pair of FFs 316, 317 has an active low reset port coupled to the output of the FF 312. However, as illustrated, the second FF 317 of the pair of FFs 316, 317 has an active high reset port coupled to the output of the FF 312. Accordingly, until the FF 312 outputs a high voltage (logical “1), the FFs 316, 317 will be disabled.

As illustrated in FIG. 3C, an inverter 333 can cause the FF 312 to change its output upon the first negative edge of the single ended internal ADC/DAC reference signal 231 after the SET signal 207 is enabled with a high voltage (logical “1’). As illustrated, the input voltage to the D port of the FF 312 can be coupled to a rail voltage Vdd, which can also be a high voltage (logical “1”). Accordingly, the output of the FF 312 can also be driven to the high voltage (logical “1”) upon the first negative edge of the single ended internal ADC/DAC reference signal 231 after the SET signal 207 is enabled. In turn, the FFs 316, 317 will no longer be reset by the FF 312 and can begin frequency division of the single ended internal ADC/DAC reference signal 231 on the next rising edge of the single ended internal ADC/DAC reference signal 231. In the illustrated example, the FFs 316, 317 the inverting output of FF 316 is coupled to the input of FF 317. Similarly, the inverting output of FF 317 is coupled to the input of FF 316. As illustrated, the clock ports of the FFs 316, 317 are both coupled to the DAC reference signal 231, thereby providing for synchronous clock generation by the clock generator 215.

### Generation of Set Signal

Referring again to FIG. 3A, the single ended internal ADC/DAC reference signal 231 may be provided as an input to a SET signal generator 310. As illustrated, the DAC_EN signal 205 may be provided as an additional input to the SET signal generator 310. In some implementations (not shown), the SET signal generator 310 can be included in the clock generator 215. In some implementations, the SET signal 207 can be the output of the SET signal generator 310.

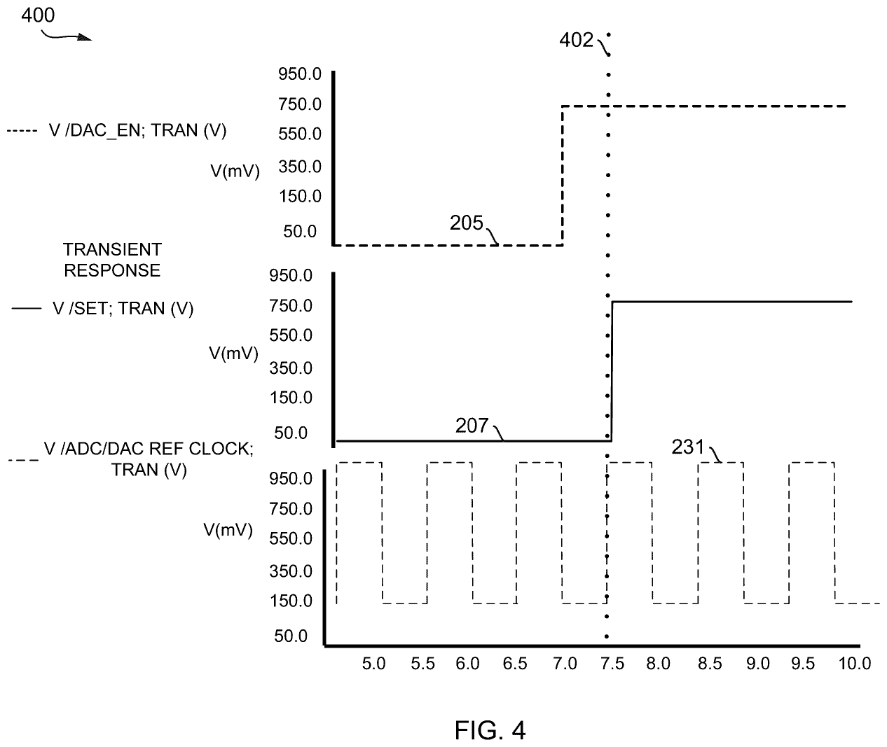

Referring now to FIG. 4, timing waveforms 400 are provided to illustrate generation of the SET signal 207. As illustrated, the DAC_EN signal 205 can have an unknown phase relative to the single ended internal ADC/DAC reference signal 231 and can be sampled asynchronously by the SET signal generator 310. As noted above, in some cases, the DAC_EN signal 205 can be derived from a synchronization signal (e.g., L1_sync, L2_sync) A vertical dotted line 402 marks the first rising edge of the single ended internal ADC/DAC reference signal 231 following the change to a high voltage (logical “1”) of the DAC_EN signal 205. As illustrated, the SET signal 207 may also change to a high voltage (logical “1”) within a short delay after the rising edge of the single ended internal ADC/DAC reference signal 231.

### Generating Digital Reference Clock(s) for ADC

FIG. 3D illustrates an example configuration 390 for generating digital reference clocks using clock generator 235. Similar to the clock generator 215, the clock generator 235 uses a pair of FFs 323 configured as divide by two (2) dividers connected in series to generate a digital reference clock 245 having a frequency of one fourth (1/4^{th}) of the ADC/DAC reference signal 121 frequency. In some cases, the clock generator 235 can generate multiple digital reference clocks for use with serializers and/or deserializers.

The clock generator 235 also includes a FF 322 configured to enable generation of the digital reference clock 245 only when a SET signal 207 is activated. In some implementations, the DAC_EN signal 205 can be a signal derived based on one or more synchronization signals (e.g., L1_sync, L2_sync) that may be used for synchronization operations between various components of a communication system (e.g., communication system 100 of FIG. 1). In the illustrated example of FIG. 3D, the SET signal 207 is connected to a buffer 255 and the output of the buffer is connected to an active low reset port of the FF 322. In some cases, the buffer 255 can introduce a delay to the SET signal 207.

Accordingly, as long as SET signal 207 has a low voltage (logical “0”), the output of the FF 322 will be reset to a low voltage (logical “0”). As illustrated, the pair of FFs 323 of the frequency divider have active low reset ports connected to the output of the FF 322. Accordingly, until the FF 322 outputs a high voltage (logical “1), the FFs 323 will be disabled.

As illustrated in the example configuration 390 of FIG. 3D, an inverter 333 can cause the FF 322 to change its output upon the first negative edge of the single ended internal ADC/DAC reference signal 231 after the SET signal 207 is enabled with a high voltage (logical “1’). As illustrated, the input voltage to the D port of the FF 322 can be coupled to a rail voltage Vdd, which can also be a high voltage (logical “1”). Accordingly, the output of the FF 322 can also be driven to the high voltage (logical “1”) upon the first negative edge of the single ended internal ADC/DAC reference signal 231 after the SET signal 207 is enabled. In turn, the FFs 323 will no longer be reset by the FF 322 and can begin frequency division of the single ended internal ADC/DAC reference signal 231 on the next rising edge of the single ended internal ADC/DAC reference signal 231 to generate digital reference clocks (e.g., digital reference clock 245, phase offset digital reference clocks 247). As illustrated in FIG. 3D, the FFs 323 of clock generator 235 are coupled in an asynchronous configuration similar to the configuration shown for FFs 314, 315 of the clock generator 215 in FIG. 3B. However, it should be understood that other configurations, such as the configuration shown for FFs 316, 317 of the clock generator 215 in FIG. 3C for synchronous clock generation, as well as other configurations for frequency division can be used without departing from the scope of the present disclosure.

In one illustrative example, the digital output of ADC 206 may be provided to four serializers (not shown) operating based on four digital reference clocks operating at the frequency of the digital reference clock 245. In some cases, each of the four serializers can be provided with a corresponding respective phase offset digital reference clock 247 with a different phase (e.g., 0°, 90°, 180°, 270°). In some configurations, at each clock cycle of the single ended internal ADC/DAC reference signal 231, one of the four serializers can be triggered by its respective phase offset digital reference clock 247. As a result, the four serializers operating at 1/4^{th} of the single ended internal ADC/DAC reference signal 231 frequency can collectively handle the digital outputs of the ADC generated at the single ended internal ADC/DAC reference signal 231 frequency.

In one illustrative example, the four serializers can each include a respective data stream comprising seven (7) bit data at approximately 245 MHz. As such, the ADC 206 output may include four possible digital streams having four (4) different possible phases of signals output. Additionally, the reference clock delay is introduced into the four (4) different possible phases thus causing a delay in the Q channel of the generated digital signals.

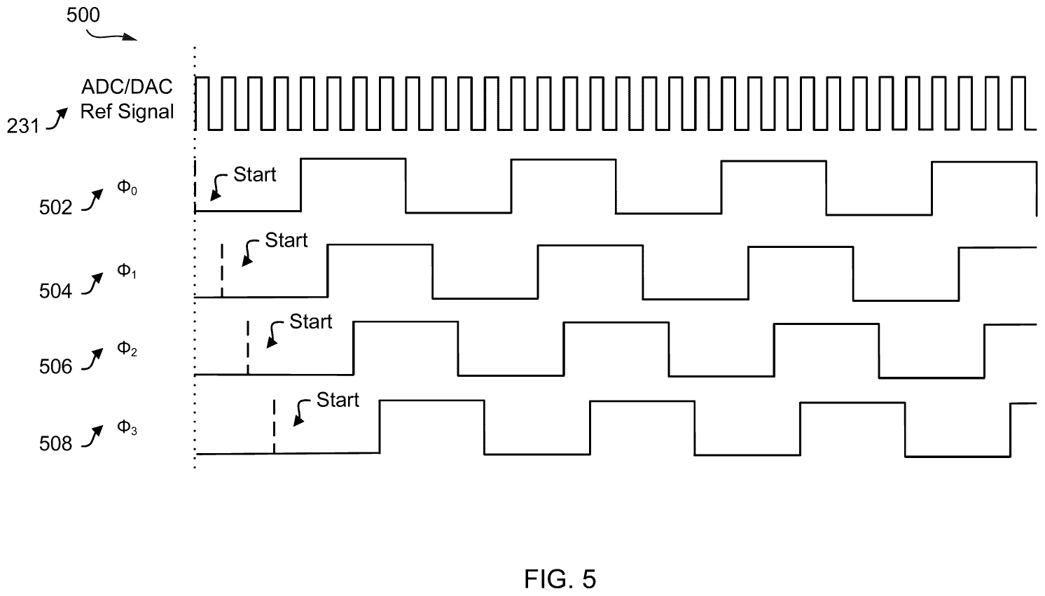

FIG. 5 illustrates an example plot 500 of four (4) different phase offsets Φ₀, Φ₁, Φ₂, and Φ₃, indicated as 502, 504, 506, and 508, respectively, for phase offset digital reference clocks 247 generated based on a single ended internal ADC/DAC reference signal 231 as described with respect to FIG. 2 and FIG. 3D. As illustrated in FIG. 5, a starting clock cycle of the internal single ended ADC/DAC reference signal 231 for each phase offset of the phase offset digital reference clocks 247 is shown. As should be apparent from FIG. 5, any other starting clock cycle will produce a digital reference clock having one of the phase offsets Φ₀ through Φ₃.

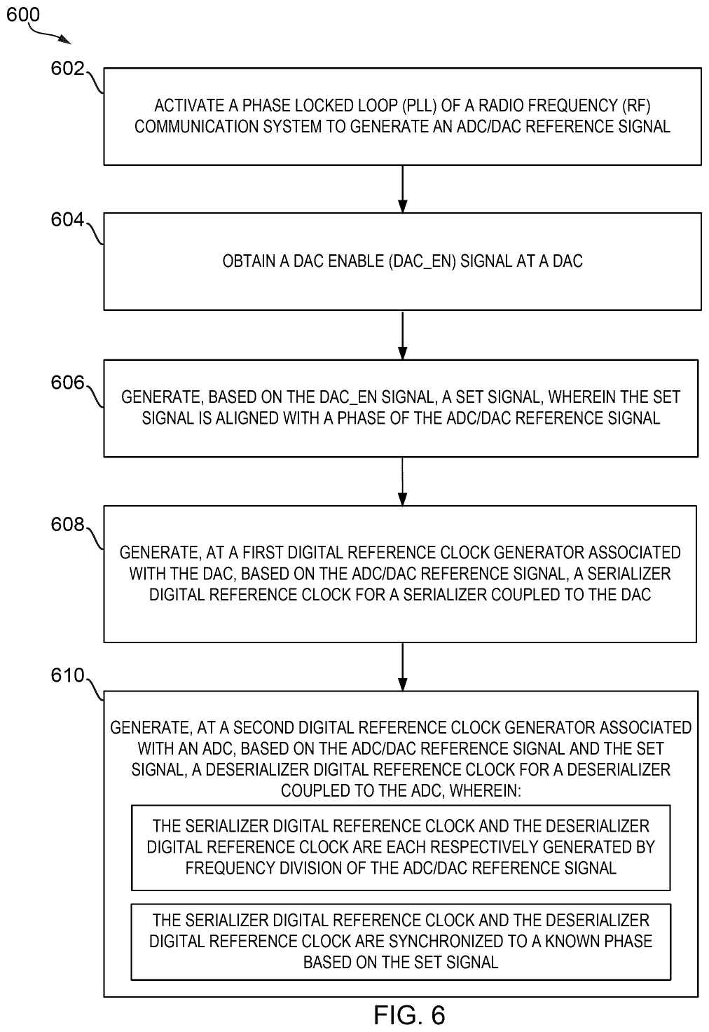

FIG. 6 is a flowchart depicting a method 600 for synchronizing digital reference clock signals for DAC serializers and Analog-to-Digital converter ADC deserializers.

At step 602, the method 600 includes activating a phase locked loop (PLL), such as the RF PLL 130 of a radio frequency (RF) communication system 100. Upon activation, the RF PLL 130 generates an ADC/DAC reference signal (e.g., the ADC/DAC reference signal 231 of FIG. 2).

At step 604, The method includes obtaining a DAC_EN signal (e.g., DAC_EN signal 205 of FIG. 2) at a DAC (e.g., DAC 204 of FIG. 2).

At step 606, the method 600 includes generating, based on the DAC_EN signal, a SET signal (e.g., SET signal 207 of FIG. 2 through FIG. 4), wherein the SET signal is aligned with a phase of the ADC/DAC reference signal. According to one or more implementations, the DAC_EN signal 205 can be a signal derived based on one or more synchronization signals (e.g., L1_sync, L2_sync) that may be used for synchronization operations between various components of a communication system.

At step 608, the method 600 includes generating, at a first digital reference clock generator (e.g., clock generator 215 of FIG. 2) associated with the DAC, based on the ADC/DAC reference signal, a serializer digital reference clock for a serializer coupled to the DAC.

Next at step 610, the method 600 includes generating, at a second digital reference clock generator (e.g., clock generator 235 of FIG. 2) associated with an ADC, based on the ADC/DAC reference signal and the SET signal, a deserializer digital reference clock for a deserializer coupled to the ADC. According to at least one implementation, the serializer digital reference clock and the deserializer digital reference clock are each respectively generated by frequency division of the ADC/DAC reference signal. Additionally, the serializer digital reference clock and the deserializer digital reference clock are synchronized to a known phase based on the SET signal.

In some implementations, the method 600 includes in a receive mode, deserializing, by the deserializer, a portion of a serial digital output of the ADC. In some examples, the deserializer is clocked by the deserializer digital reference clock. In some embodiments, the method 600 includes, in a transmit mode, serializing, by the serializer, a serial digital input to the DAC. In some cases, the serializer is clocked by the serializer digital reference clock.

In some cases, the ADC/DAC reference signal has a bandwidth of at least twice that of a signal being converted at the ADC or a signal being converted at the DAC. In some examples, the ADC/DAC reference signal has a bandwidth of at least twice that of a signal being converted at the ADC or a signal being converted at the DAC.

In some implementations, the ADC/DAC reference signal is a differential signal and wherein the ADC/DAC reference signal is converted within the RF communication system to a single ended internal ADC/DAC reference signal. In some cases, a voltage of the SET signal changes to a high voltage after a rising edge of the single ended internal ADC/DAC reference signal following activation of the DAC_EN signal is identified.

In some examples, the DAC_EN signal is synchronized to a synchronization signal of the RF communication system. In some implementations, the DAC_EN signal is coupled to an active low reset port of a frequency divider of the RF communication system and the frequency divider is configured to generate the serializer digital reference clock.

In some examples, the SET signal is generated by a SET signal generator. In some cases, the SET signal includes a delay provided by one or more buffers.

In some implementations, a frequency of the ADC/DAC reference signal is divided by two (2) or four (4) to generate the serializer digital reference clock and the deserializer digital reference clock. In some examples, a frequency of the ADC/DAC reference signal is divided using one or more flip-flops to generate the serializer digital reference clock and the deserializer digital reference clock.

In some cases, a plurality of deserializer reference clocks includes the deserializer digital reference clock and each deserializer reference clock of the plurality of deserializer reference clocks has a respective different phase. In some implementations, the plurality of deserializer reference clocks includes four deserializer reference clocks. In some aspects, the respective different phases for the four deserializer reference clocks have ninety degree (90°) phase increments.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

1. A method for synchronizing digital reference clock signals for Digital-to-analog converter (DAC) serializers and Analog-to-Digital converter (ADC) deserializers in a radio frequency (RF) communication system, the method comprising:
activating a phase locked loop (PLL) of a radio frequency (RF) communication system to generate an ADC/DAC reference signal;
obtaining a DAC Enable (DAC_EN) signal at a DAC;
generating, based on the DAC_EN signal, a SET signal, wherein the SET signal is aligned with a phase of the ADC/DAC reference signal;
generating, at a first digital reference clock generator associated with the DAC, based on the ADC/DAC reference signal, a serializer digital reference clock for a serializer coupled to the DAC; and
generating, at a second digital reference clock generator associated with an ADC, based on the ADC/DAC reference signal and the SET signal, a deserializer digital reference clock for a deserializer coupled to the ADC, wherein:
the serializer digital reference clock and the deserializer digital reference clock are each respectively generated by frequency division of the ADC/DAC reference signal; and
the serializer digital reference clock and the deserializer digital reference clock are synchronized to a known phase based on the SET signal.

2. The method of claim 1, further comprising:
in a receive mode, deserializing, by the deserializer, a portion of a serial digital output of the ADC, wherein the deserializer is clocked by the deserializer digital reference clock; and
in a transmit mode, serializing, by the serializer, a serial digital input to the DAC, wherein the serializer is clocked by the serializer digital reference clock.

3. The method of claim 1, wherein the ADC/DAC reference signal has a bandwidth of at least twice that of a signal being converted at the ADC or a signal being converted at the DAC.

4. The method of claim 1, wherein the ADC/DAC reference signal is a differential signal and wherein the ADC/DAC reference signal is converted within the RF communication system to a single ended internal ADC/DAC reference signal.

5. The method of claim 4, wherein a voltage of the SET signal changes to a high voltage after a rising edge of the single ended internal ADC/DAC reference signal following activation of the DAC_EN signal is identified.

6. The method of claim 1, wherein the DAC_EN signal is synchronized to a synchronization signal of the RF communication system.

7. The method of claim 6, wherein the DAC_EN signal is coupled to an active low reset port of a frequency divider of the RF communication system, wherein the frequency divider is configured to generate the serializer digital reference clock.

8. The method of claim 1, wherein the SET signal is generated by a SET signal generator.

9. The method of claim 1, wherein the SET signal includes a delay provided by one or more buffers.

10. The method of claim 1, wherein a frequency of the ADC/DAC reference signal is divided by two (2) or four (4) to generate the serializer digital reference clock and the deserializer digital reference clock.

11. The method of claim 1, wherein a frequency of the ADC/DAC reference signal is divided using one or more flip-flops to generate the serializer digital reference clock and the deserializer digital reference clock.

12. The method of claim 1, wherein:
a plurality of deserializer reference clocks comprises the deserializer digital reference clock; and
each deserializer reference clock of the plurality of deserializer reference clocks has a respective different phase.

13. The method of claim 12, wherein the plurality of deserializer reference clocks comprises four deserializer reference clocks, wherein the respective different phases for the four deserializer reference clocks comprise ninety degree (90°) phase increments.

14. An apparatus for synchronizing digital reference signals for DAC serializers and ADC deserializers, the apparatus comprising:
a PLL configured to obtain generate an ADC/DAC reference signal;
a SET signal generator included within a DAC and configured to obtain a DAC_EN signal and to generate a SET signal based on an activation of the DAC_EN signal, wherein the SET signal is aligned with a phase of the ADC/DAC reference signal;
a first digital reference clock generator associated with the DAC and configured to generate a serializer digital reference clock based on the ADC/DAC reference signal by frequency dividing the ADC/DAC reference signal; and
a second digital reference clock generator associated with an ADC and configured to generate a deserializer digital reference clock based on the ADC/DAC reference signal by frequency dividing the ADC/DAC reference signal, wherein the serializer digital reference clock and the deserializer digital reference clock are synchronized to a known phase based on the SET signal.

15. The apparatus of claim 14, further comprising:
a deserializer configured to, in a receive mode, deserialize a portion of a serial digital output of the ADC, wherein the deserializer is clocked by the deserializer digital reference clock; and
a serializer configured to, in a transmit mode, serialize a serial digital output of the ADC, wherein the serializer is clocked by the serializer digital reference clock.

16. The apparatus of claim 14, wherein the ADC/DAC reference signal has a bandwidth to be at least twice that of a signal being converted at ADC or the DAC.

17. The apparatus of claim 14, wherein the ADC/DAC reference signal is a differential signal and wherein the ADC/DAC reference signal is converted to a single ended internal ADC/DAC reference signal by a differential to single-ended converter.

18. The apparatus of claim 17, wherein a voltage of the SET signal changes to a high voltage signal after a rising edge of the single ended internal ADC/DAC reference signal following activation of the DAC_EN signal is identified.

19. The apparatus of claim 14, wherein the DAC_EN signal is synchronized to a synchronization signal of a phased array antenna system.

20. The apparatus of claim 14 wherein the DAC_EN signal is coupled to an active low reset port of a frequency divider, wherein the frequency divider is configured to generate the serializer digital reference clock. 21 The apparatus of claim 14, wherein the SET signal is generated at a SET signal generator.

22. The apparatus of claim 14, wherein the SET signal includes a delay provided by one or more buffers. 23 The apparatus of claim 14, wherein a frequency of the ADC/DAC reference signal is divided by two (2) or four (4) to generate the serializer digital reference clock and the deserializer digital reference clock.

24. The apparatus of claim 14, wherein a frequency of the ADC/DAC reference signal is divided using one or more flip-flops to generate the serializer digital reference clock and the deserializer digital reference clock.

25. The apparatus of claim 14, wherein:
a plurality of deserializer reference clocks comprises the deserializer digital reference clock; and
each deserializer reference clock of the plurality of deserializer reference clocks has a respective different phase.

26. The apparatus of claim 25, wherein:
the plurality of deserializer reference clocks comprises four deserializer reference clocks; and
the respective different phases for the four deserializer reference clocks comprise ninety degree (90°) phase increments.
